(19) United States
(12) Patent Application Publication
(10) Pub. No.: US 2026/0331191 A1
(43) Pub. Date: Oct. 22, 2026

(54) FAIL BITS DETECTION DEVICE AND METHOD FOR FLASH MEMORY

(71) Applicant: MACRONIX International Co., Ltd., Hsinchu (TW)

(72) Inventors: Chung-Han Wu, Kaohsiung City (TW); Chih-He Chiang, Hsinchu County (TW)

(73) Assignee: MACRONIX International Co., Ltd., Hsinchu (TW)

(21) Appl. No.: 19/184,438

(22) Filed: Apr. 21, 2025

(51) Int. Cl. G11C 16/34; G11C 5/14; G11C 16/32

(52) U.S. Cl. CPC G11C 16/3459; G11C 5/146; G11C 16/32

(57) ABSTRACT

A fail bits detection device and a fail bits detection method for a flash memory, which can be a three-dimensional NAND flash memory with high capacity and high performance, are provided. The fail bits detection device includes a capacitive conductor, a precharging circuit, a conversion circuit and a judgment circuit. The precharging circuit precharges the capacitive conductor. The conversion circuit converts present logic values of different data buses of a page buffer of the flash memory into a discharge current. The conversion circuit draws the discharge current from the capacitive conductor. The judgment circuit checks a node voltage of the capacitive conductor. The judgment circuit determines a falling time length based on a falling speed of the node voltage during a determination period. The judgment circuit determines whether the present logic values of the different data buses are failed based on the falling time length.

### BACKGROUND

### Technical Field

The disclosure relates to a memory circuit, and in particular to a fail bits detection device and a method for a flash memory.

### Description of Related Art

Integrated circuits, including three-dimensional NAND flash memory (3D NAND flash memory) with high capacity and high performance, are continuously developing. To overcome the issue of size reduction, the NAND flash memory industry has transitioned from a planar architecture to a 3D architecture. The storage capacity of 3D vertical NAND flash memory has continuously increased over the past decade to meet the demands of various industries, including mobile devices and data centers. The increase in the number of stacked word-line (WL) layers plays a key role in achieving higher storage capacity or bit density. This paradigm shift allows for increased storage density by vertically stacking storage cells instead of relying solely on cell miniaturization. Charge-trap technology uses a continuous silicon nitride layer as a storage node (SN). Compared to floating gate technology, charge-trap technology is widely used in 3D NAND flash memory arrays due to its simpler fabrication process and higher vertical scaling capability.

With technological advancements, the number of stacked layers in integrated circuits is increasing, leading to higher bit density, thereby enabling NAND flash memory products to have larger storage capacity. As capacity increases, the fail bits detection device will play an important role in the chip.

### SUMMARY

The disclosure provides a fail bits detection device and a method for a flash memory to determine whether multiple present logic values of multiple data buses of a page buffer of the flash memory are failed.

In an embodiment of the disclosure, a fail bits detection device includes a capacitive conductor, a precharging circuit, a conversion circuit, and a judgment circuit. The precharging circuit is coupled to the capacitive conductor. The precharging circuit precharges the capacitive conductor during a precharge period. Multiple input terminals of the conversion circuit are coupled to multiple different data buses of a page buffer of the flash memory. The conversion circuit converts multiple present logic values of the different data buses into a discharge current during a determination period after the precharge period. A current terminal of the conversion circuit is coupled to the capacitive conductor. The conversion circuit draws the discharge current from the capacitive conductor during the determination period. The judgment circuit is coupled to the capacitive conductor. The judgment circuit checks a node voltage of the capacitive conductor during the determination period. The judgment circuit determines a falling time length based on a falling speed of the node voltage during the determination period. The judgment circuit determines whether the present logic values of the different data buses are failed based on the falling time length.

In an embodiment of the disclosure, the fail bits detection method includes the following steps. A precharging circuit of the flash memory precharges a capacitive conductor of the flash memory during a precharge period. Multiple present logic values of multiple different data buses of a page buffer of the flash memory is converted into a discharge current during a determination period after the precharge period by a conversion circuit of the flash memory. The discharge current is drawn from the capacitive conductor during the determination period by the conversion circuit. A node voltage of the capacitive conductor is checked during the determination period by a judgment circuit of the flash memory. A falling time length is determined based on a falling speed of the node voltage during the determination period by the judgment circuit. Whether the present logic values of the different data buses are failed is determined based on the falling time length by the judgment circuit.

Based on the above, in the embodiments of the disclosure, the conversion circuit draws the discharge current from the capacitive conductor based on the present logic values of the different data buses. In response to fewer fail bits in the present logic values, the conversion circuit draws a smaller discharge current from the capacitive conductor, causing the falling speed of the node voltage of the capacitive conductor to be slower (resulting in a longer falling time length). Conversely, in response to more fail bits in the present logic values, the conversion circuit draws a greater discharge current from the capacitive conductor, causing the falling speed of the node voltage of the capacitive conductor to be faster (resulting in a shorter falling time length). A shorter falling time length means that the time required for fail bits detection is reduced. The programming operation of the flash memory includes multiple programming loops to perform an increment-step-pulse-programming (ISPP) operation. Generally, the present logic values in the first few programming loops of the programming operation contains more fail bits. The fail bits detection device of the embodiments of the disclosure can effectively reduce the time required for fail bits detection in the first few programming loops of the programming operation.

To make the features and advantages of the disclosure more comprehensible, several embodiments accompanied with drawings are described in detail as follows.

### BRIEF DESCRIPTION OF THE DRAWINGS

FIG. 1 is a schematic diagram of a circuit block of a non-volatile memory integrated circuit according to an embodiment of the disclosure.

FIG. 2 is a schematic diagram of a circuit block of a non-volatile memory integrated circuit according to an embodiment of the disclosure.

FIG. 3 is a schematic diagram of a circuit block of a fail bits detection device according to an embodiment of the disclosure.

FIG. 4 is a flowchart illustrating a fail bits detection method for a flash memory according to an embodiment of the disclosure.

FIG. 5 is a schematic diagram of a circuit block illustrating a precharging circuit, a judgment circuit, and a conversion circuit according to an embodiment.

FIG. 6 is a signal diagram illustrating the precharge period and the determination period according to an embodiment of the disclosure.

FIG. 7 is a schematic diagram of a circuit block illustrating a judgment circuit and a conversion circuit according to another embodiment.

FIG. 8 is a schematic diagram of a circuit block illustrating a judgment circuit and a conversion circuit according to yet another embodiment.

FIG. 9 is a schematic diagram of a circuit block illustrating a judgment circuit 320 and a conversion circuit 340 according to still another embodiment.

### DESCRIPTION OF THE EMBODIMENTS

In this specification (including the claims), the term “coupled to (or connected to)” may refer to any direct or indirect connection means. For example, if the text describes that a first device is coupled to (or connected to) a second device, it should be interpreted that the first device may be directly connected to the second device, or the first device may be indirectly connected to the second device through other devices or certain connection means. The terms “first,” “second,” and the like mentioned in this specification (including the claims) are used to name elements or distinguish different embodiments or scopes, and are not intended to limit the upper or lower quantity limits of the elements, nor to impose restrictions on the order of the elements. Additionally, wherever possible, elements/components/steps in the figures and embodiments that use the same reference numerals represent the same or similar parts. Elements/components/steps that use the same reference numerals or the same terminology in different embodiments may be cross-referenced to related descriptions.

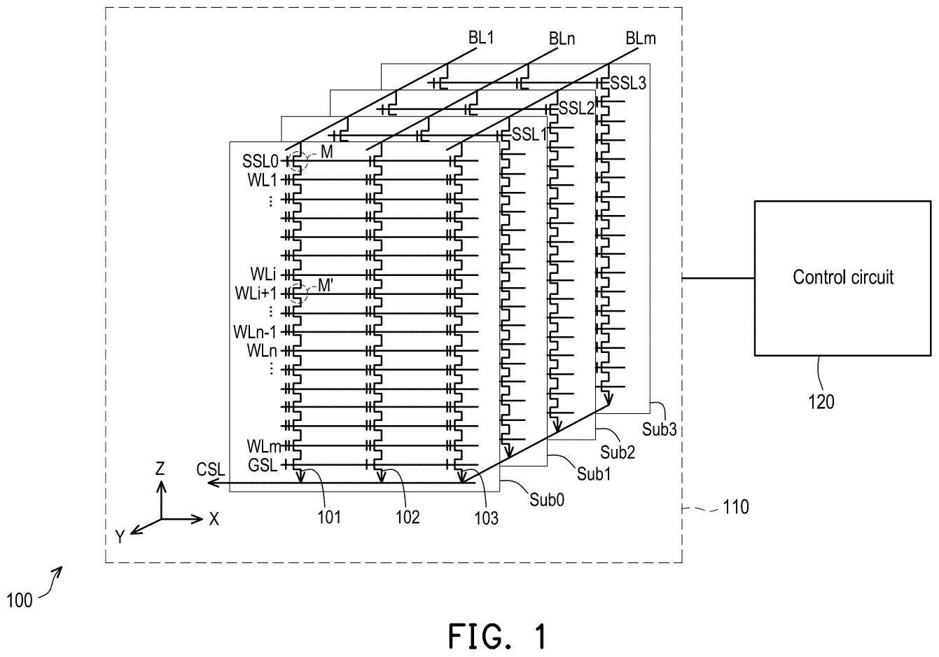

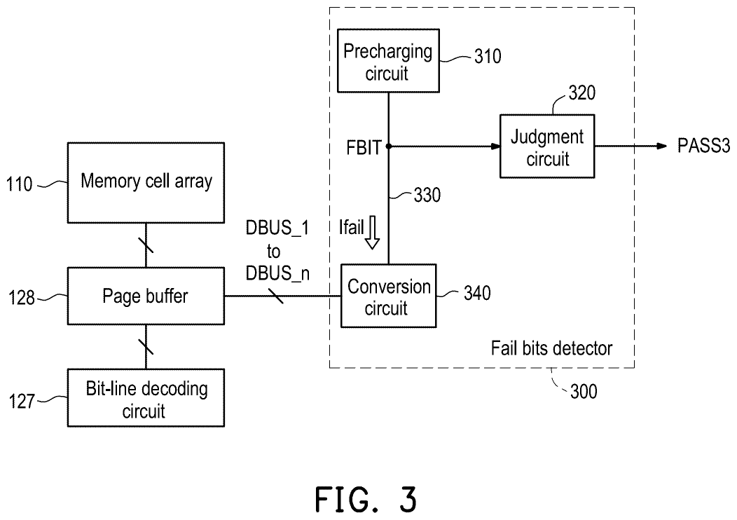

FIG. 1 is a schematic diagram of a circuit block of a non-volatile memory integrated circuit 100 according to an embodiment of the disclosure. The non-volatile memory integrated circuit 100 includes a memory cell array 110 and a control circuit 120. The control circuit 120 is coupled to the memory cell array 110. The memory cell array 110 shown in FIG. 1 may be one of many implementation examples of the memory cell array 110 shown in FIG. 3, and the control circuit 120 shown in FIG. 3 may be one of many implementation examples of the control circuit 120 shown in FIG. 1. Depending on different designs, in some embodiments, the control circuit 120 may be implemented as a hardware circuit. In other embodiments, the control circuit 120 may be implemented in a combination of hardware, firmware, and software (i.e., programs).

In hardware form, the control circuit 120 may be implemented as a logic circuit on an integrated circuit. For example, the related functions of the control circuit 120 may be implemented in one or more hardware controllers, microcontrollers, hardware processors, microprocessors, application-specific integrated circuits (ASICs), digital signal processors (DSPs), field-programmable gate arrays (FPGAs), central processing units (CPUs), and/or other processing units, in various logic blocks, modules, and circuits. The related functions of the control circuit 120 may be implemented as hardware circuits using a hardware description language (such as Verilog HDL or VHDL) or other suitable programming languages, for example, in various logic blocks, modules, and circuits in an integrated circuit.

In software form and/or firmware form, the related functions of the control circuit 120 may be implemented as programming codes. For example, the control circuit 120 may be implemented using general programming languages (such as C, C++, or assembly language) or other suitable programming languages. The programming codes may be recorded/stored in a non-transitory machine-readable storage medium. In some embodiments, the non-transitory machine-readable storage medium may include, for example, a semiconductor memory and/or a storage device. An electronic device (such as a CPU, hardware controller, microcontroller, hardware processor, or microprocessor) may read and execute the programming codes from the non-transitory machine-readable storage medium to realize the related functions of the control circuit 120.

FIG. 1 illustrates an equivalent circuit of a three-dimensional (3D) NAND flash memory integrated circuit in a 3D manner. The memory cell array 110 includes a plurality of memory cells (such as a memory cell M′). The plurality of memory cells in the memory cell array 110 shown in FIG. 1 are arranged in a 3D manner in an XYZ coordinate system. However, this does not mean that the circuit of the memory cell array 110 is limited to a 3D arrangement. In an example, the memory cell array 110 may be divided into four sub-blocks Sub0, Sub1, Sub2, and Sub3. The control circuit 120 may independently control the operation of each sub-block (such as sub-block Sub0).

Each memory cell string shown in FIG. 1 (such as a memory cell string 101, 102, or 103) includes a plurality of memory cells (such as the memory cell M') that are connected in series along the Z direction. The memory cell array 110 includes a plurality of word lines (WLs), such as word lines WL1, . . . , WLi, WLi+1, . . . , WLn-1, WLn, . . . , and WLm shown in FIG. 1. A word line (such as the word line WLn) may correspond to a layer in the XY plane. Each of the word lines WL1 to WLm is coupled to a corresponding row of a plurality of memory cells. The plurality of memory cells in each memory cell string (such as the memory cell string 101) correspond to a word line (such as the word line WLi+1). The memory cell M may be configured as a string selection transistor coupled to a string select line (SSL), such as string select line SSL0, SSL1, SSL2, or SSL3, and another memory cell may be configured as a ground selection transistor coupled to a ground select line (GSL). The string selection transistor and the ground selection transistor are located at opposite sides of each memory cell string (such as the memory cell string 101). In this example, a plurality of memory cell strings (such as the memory cell strings 101, 102, etc.) that are coupled to the same string select line (such as the string select line SSL0) on the same plane (such as the plane defined by the X direction and the Z direction) may be defined as a sub-block (such as the sub-block Sub0).

Each of a plurality of bit lines (BLs) is coupled to a corresponding column of a plurality of memory cells. That is, each memory cell string (such as the memory cell string 101, 102, or 103) is connected to a corresponding bit line (such as the bit line BL1, BLn, or BLm) through a corresponding string selection transistor on the string select line (such as the string select line SSL0). The memory cell strings (such as the memory cell string 101) of the same column in different sub-blocks (such as the sub-blocks Sub0, Sub1, etc.) along the Y direction are connected to a corresponding bit line (such as the bit line BL1). The string select line (such as the string select line SSL0) may be a conductive wire or conductive layer formed above the topmost word line layer (such as the word line WL1). Each memory cell string (such as the memory cell string 101, 102, or 103) may be connected to the same common source line (CSL) through a corresponding ground selection transistor on the ground select line (GSL). The ground select line GSL may be a conductive wire or conductive layer formed below the bottommost word line layer (such as the word line WLm). The common source line CSL may be a conductive layer formed above the substrate of the non-volatile memory integrated circuit 100. The string select lines (such as the string select lines SSL0 to SSL3) in the memory cell array 110 may be formed on the same conductive layer but divided into independent lines. Each independent line (string select line) may independently control the operation of a corresponding sub-block (such as the sub-blocks Sub0, Sub1, etc.) in the memory cell array 110.

In an example, in a single-level cell (SLC) configuration, a plurality of memory cells (including the memory cell M′) in a sub-region (such as the sub-region Sub0) that are coupled to the same word line or word line layer (such as the word line WLn) may be defined as a page. In another example, in a triple-level cell (TLC) configuration, a plurality of memory cells (including the memory cell M′) in a sub-region (such as the sub-region Sub0) that are coupled to the same word line or word line layer (such as the word line WLn) may be defined as three pages. In the TLC configuration, these three pages include a high page, a middle page, and a low page. The memory cell M′ located on the same word line (such as the word line WLn) is applied with the same voltage. Each word line (such as the word line WLn) may be connected to a driving circuit, such as an X-decoder (or a scan driver).

In an example, one or more dummy lines or layers (not shown) may be provided between the string select line (such as the string select lines SSL0 to SSL3) and the word line layer (such as the word line WL1), as well as between the ground select line GSL and the bottommost word line layer (such as the word line WLm). In another example, one or more dummy lines or layers (not shown) may be provided in the middle portion of each memory cell string (such as the memory cell strings 101, 102, or 103). The non-volatile memory integrated circuit 100 further includes a control circuit 120, which is used to implement corresponding operations on the memory cell array 110.

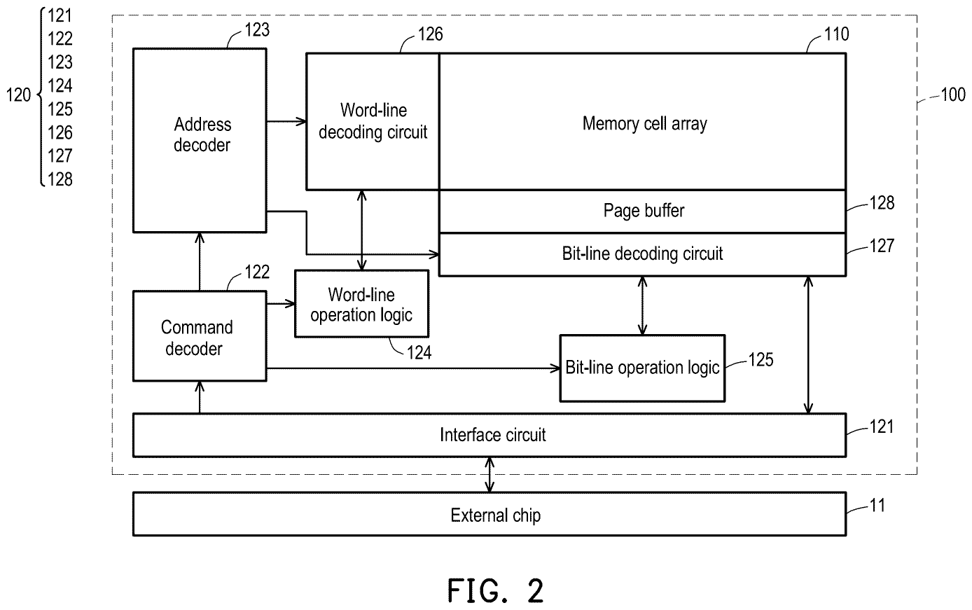

FIG. 2 is a schematic diagram of a circuit block of a non-volatile memory integrated circuit 100 according to an embodiment of the disclosure. The non-volatile memory integrated circuit 100 shown in FIG. 2 may be referenced with the related description of FIG. 1. An external chip 11 transmits commands to the non-volatile memory integrated circuit 100 and transmits and receives data to and from the non-volatile memory integrated circuit 100. Based on the control of the external chip 11 (such as a memory controller), the non-volatile memory integrated circuit 100 shown in FIG. 2 provides data access functionality to the external chip 11. In the embodiment shown in FIG. 2, the control circuit 120 includes an interface circuit 121, a command decoder 122, an address decoder 123, a word-line operation logic 124, a bit-line operation logic 125, a word-line decoding circuit 126, a bit-line decoding circuit 127, and a page buffer 128.

The command decoder 122 receives commands (such as programming commands, read mode commands, write mode commands, etc.) from the external chip 11 through the interface circuit 121. Upon receiving a command, the command decoder 122 decodes the command to perform a corresponding operation. For example, based on the command decoding result, the command decoder 122 transmits an array address to the address decoder 123. Based on the control of the command decoder 122, the word-line operation logic 124 notifies the word-line decoding circuit 126 of the word-line (WL) to be selected and the word-line to be deselected. The address decoder 123 decodes the array address and transmits the address decoding result to the word-line decoding circuit 126 and the bit-line decoding circuit 127. Based on the control of the address decoder 123 and the word-line operation logic 124, the word-line decoding circuit 126 selects a corresponding word-line of the memory cell array 110.

Based on the control of the command decoder 122, the bit-line operation logic 125 notifies the bit-line decoding circuit 127 of the bit-line (BL) to be selected and the bit-line to be deselected. Based on the control of the address decoder 123 and the bit-line operation logic 125, the bit-line decoding circuit 127 transmits and receives data to and from the external chip 11 through the interface circuit 121. The bit-line decoding circuit 127 selects a corresponding bit-line of the memory cell array 110 based on the control of the bit-line operation logic 125. The page buffer 128 includes a sense amplifier, which is used to sense the signal of the bit-line to generate corresponding data.

FIG. 3 is a schematic diagram of a circuit block of a fail bits detection device 300 according to an embodiment of the disclosure. The memory cell array 110, the page buffer 128, and the bit-line decoding circuit 127 shown in FIG. 3 may be referenced with the related description of FIG. 2 and will not be redundantly described. Based on practical applications, the fail bits detection device 300 may be arranged in any functional circuit in the non-volatile memory integrated circuit 100. The fail bits detection device 300 shown in FIG. 3 includes a precharging circuit 310, a judgment circuit 320, a capacitive conductor 330, and a conversion circuit 340. The material of the capacitive conductor 330 may be any conductive material (such as metal). Since the capacitive conductor 330 is wound to a long length, the equivalent capacitance (parasitic capacitance) of the capacitive conductor 330 becomes very large. Therefore, the capacitive conductor 330 is capable of storing electric charge. The capacitive conductor 330 is coupled to the precharging circuit 310, the judgment circuit 320, and the conversion circuit 340.

The page buffer 128 has a plurality of data buses DBUS_0 to DBUS_n. The number n of data buses DBUS_1 to DBUS_n may be any integer determined based on actual design and application. A plurality of input terminals of the conversion circuit 340 are coupled to the different data buses DBUS_0 to DBUS_n of the page buffer 128. Based on practical applications, the conversion circuit 340 may be arranged in any functional circuit in the non-volatile memory integrated circuit 100. For example, the conversion circuit 340 may be arranged in a page buffer region.

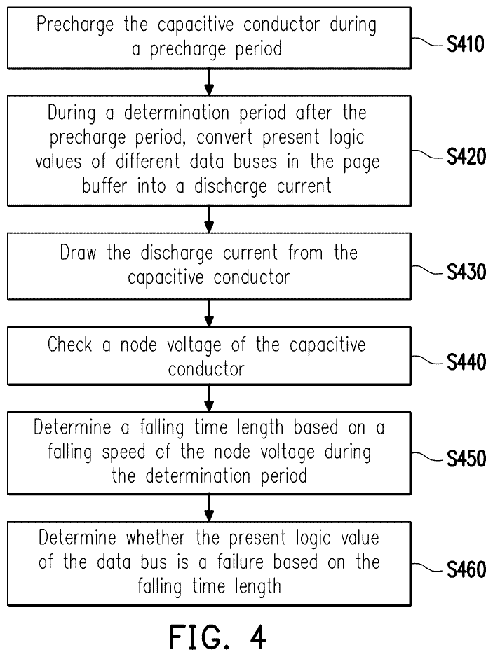

FIG. 4 is a flowchart illustrating a fail bits detection method for a flash memory according to an embodiment of the disclosure. Please refer to FIG. 3 and FIG. 4. In step S410, the precharging circuit 310 precharges the capacitive conductor 330 during a precharge period. The capacitive conductor includes a metal-routing capacitor (parasitic capacitance, not shown) to store the precharge charge outputted by the precharging circuit 310 during the precharge period. The precharging circuit 310 stops precharging the capacitive conductor 330 during a determination period after the precharge period.

The conversion circuit 340 converts present logic values of different data buses DBUS_1 to DBUS_n of the page buffer 128 into a discharge current Ifail during the determination period after the precharge period (step S420). The programming operation of the memory cell array 110 (flash memory) includes multiple programming loops to perform an increment-step-pulse-programming (ISPP) operation on a present target memory cell in the memory cell array 110. Generally, the present logic values in the first few programming loops of the programming operation contains more fail bits. That is, the present logic values of different data buses DBUS_1 to DBUS_n of the page buffer 128 contain more fail bits. The present logic value of a target data bus among data buses DBUS_1 to DBUS_n is a first logic value (such as logic value “1”), indicating that the programming result of a corresponding word line in the memory cell array 110 is a failure.

In response to the present logic value of the target data bus indicating that the programming result is a failure, the conversion circuit 340 converts the present logic value of the target data bus into a corresponding current component of the discharge current Ifail. The present logic value of the target data bus is a second logic value (such as logic value “0”), indicating that the programming result of a corresponding word line in the memory cell array 110 is a pass (successful). In response to the present logic value of the target data bus indicating that the programming result is a pass, the conversion circuit 340 abandons converting the present logic value of the target data bus into a corresponding current component of the discharge current. Therefore, the greater the number of fail bits in the present logic values of the data buses DBUS_1 to DBUS_n, the greater the discharge current Ifail. Conversely, the fewer the fail bits in the present logic values of the data buses DBUS_1 to DBUS_n, the smaller the discharge current Ifail.

A current terminal of the conversion circuit 340 is coupled to the capacitive conductor 330. The conversion circuit 340 draws the discharge current Ifail from the capacitive conductor 330 during the determination period (step S430), causing a continuous decrease in a node voltage FBIT of the capacitive conductor 330 during the determination period. The greater the number of data buses DBUS_1 to DBUS_n indicating that the programming result is a failure (that is, the greater the number of fail bits in the present logic values of the data buses DBUS_1 to DBUS_n), the greater the discharge current Ifail, resulting in a faster falling speed of the node voltage FBIT.

The judgment circuit 320 checks a node voltage FBIT of the capacitive conductor 330 during the determination period (step S440). The judgment circuit 320 determines a falling time length based on a falling speed of the node voltage FBIT during the determination period (step S450). The smaller the discharge current Ifail drawn by the conversion circuit 340 from the capacitive conductor 330, the slower the falling speed of the node voltage FBIT of the capacitive conductor 330 (resulting in a longer falling time length). Conversely, the greater the discharge current Ifail drawn by the conversion circuit 340 from the capacitive conductor 330, the faster the falling speed of the node voltage FBIT of the capacitive conductor 330 (resulting in a shorter falling time length). In step S460, the judgment circuit 320 determines whether the present logic values of different data buses DBUS_1 to DBUS_n of the page buffer 128 are failed based on the falling time length.

For example (but not limited thereto), the judgment circuit 320 compares the node voltage FBIT with a reference voltage during the determination period. The level of the reference voltage may be determined according to actual design and application. The judgment circuit 320 determines the falling time length based on a comparison result between the node voltage FBIT and the reference voltage. The judgment circuit 320 compares the falling time length with a reference time length. The reference time length may be determined according to actual design and application. The judgment circuit 320 determines whether the present logic values of different data buses DBUS_1 to DBUS_n are failed based on a comparison result between the falling time length and the reference time length.

The judgment circuit 320 notifies a next-stage circuit (not shown) through a result signal PASS3 whether the present logic values of different data buses DBUS_1 to DBUS_n of the page buffer 128 are failed. For example (but not limited thereto), if the result signal PASS3 is at a high logic level, it indicates that the present logic values pass the check, whereas if the result signal PASS3 is at a low logic level, it indicates that the present logic values fail the check. When the result signal PASS3 indicates that the present logic values fail the check, the non-volatile memory integrated circuit 100 performs the next programming loop on a present target memory cell in the memory cell array 110 until the result signal PASS3 indicates that the present logic values pass the check.

In summary, the conversion circuit 340 draws the discharge current Ifail from the capacitive conductor 330 based on the present logic values of different data buses DBUS_1 to DBUS_n of the page buffer 128. In response to fewer fail bits in the present logic values, the conversion circuit 340 draws a smaller discharge current Ifail from the capacitive conductor 330, causing a slower falling speed of the node voltage FBIT of the capacitive conductor 330 (resulting in a longer falling time length). Conversely, in response to more fail bits in the present logic values, the conversion circuit 340 draws a greater discharge current Ifail from the capacitive conductor 330, causing a faster falling speed of the node voltage FBIT of the capacitive conductor 330 (resulting in a shorter falling time length). A shorter falling time length means that the time required for fail bits detection is reduced. Generally, the present logic values in the first few programming loops of the programming operation contain more fail bits. The fail bits detection device 300 can effectively reduce the time required for fail bits detection in the first few programming loops of the programming operation.

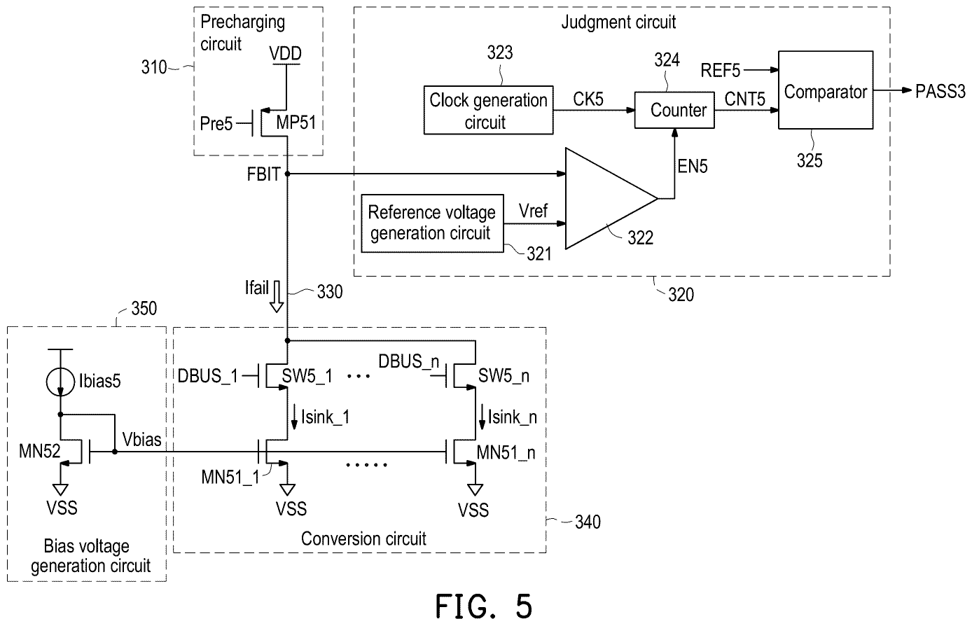

FIG. 5 is a schematic diagram of a circuit block illustrating the precharging circuit 310, the judgment circuit 320, and the conversion circuit 340 according to an embodiment. The precharging circuit 310, the judgment circuit 320, the capacitive conductor 330, and the conversion circuit 340 shown in FIG. 5 may be referenced with the related description of FIG. 3. The precharging circuit 310, the judgment circuit 320, and the conversion circuit 340 shown in FIG. 5 may be one of many implementation examples of the precharging circuit 310, the judgment circuit 320, and the conversion circuit 340 shown in FIG. 3.

In the embodiment shown in FIG. 5, the precharging circuit 310 includes a precharging transistor MP51. A first terminal (such as a source) of the precharging transistor MP51 is coupled to a power voltage source VDD. A second terminal (such as a drain) of the precharging transistor MP51 is coupled to the capacitive conductor 330. A control terminal (such as a gate) of the precharging transistor MP51 is controlled by a precharge control signal Pre5. The precharging transistor MP51 is turned on during the precharge period to precharge the capacitive conductor 330. The precharging transistor MP51 is turned off during the determination period after the precharge period to stop precharging the capacitive conductor 330.

In the embodiment shown in FIG. 5, the conversion circuit 340 includes a plurality of switches, such as switches SW5_1, . . . , SW5_n. A first terminal of each switch SW5_1 to SW5_n is coupled to the capacitive conductor 330. A control terminal of each switch SW5_1 to SW5_n is coupled to a corresponding one of the data buses DBUS_1 to DBUS_n of the page buffer 128. In the embodiment shown in FIG. 5, the conversion circuit 340 further includes a plurality of transistors, such as transistors MN51_1, . . . , MN51_n. A first terminal (such as a drain) of each transistor MN51_1 to MN51_n is coupled to a second terminal of a corresponding one of the switches SW5_1 to SW5_n. For example, a first terminal of transistor MN51_1 is coupled to a second terminal of switch SW5_1, and a first terminal of transistor MN51_n is coupled to a second terminal of switch SW5_n. A second terminal (such as a source) of each transistor MN51_1 to MN51_n is coupled to a reference voltage source VSS. A control terminal (such as a gate) of each transistor MN51_1 to MN51_n is controlled by a bias voltage Vbias.

For example, in response to the present logic values of all data buses DBUS_1 to DBUS_n being logic value “0” (indicating that the programming result is a pass), all switches SW5_1 to SW5_n are turned off, and therefore, the discharge current Ifail is relatively small (or even zero). In response to the present logic value of data bus DBUS_1 being logic value “1” (indicating that a bit has a programming failure), switch SW5_1 is turned on. Thus, the conversion circuit 340 converts the present logic value of data bus DBUS_1 into a corresponding current component Isink_1 of the discharge current Ifail. Similarly, in response to the present logic value of data bus DBUS_n being logic value “1,” switch SW5_n is turned on. Thus, the conversion circuit 340 converts the present logic value of data bus DBUS_n into a corresponding current component Isink_n of the discharge current Ifail.

In the embodiment shown in FIG. 5, the fail bits detection device 300 further includes a bias voltage generation circuit 350. The bias voltage generation circuit 350 is coupled to the conversion circuit 340 to provide a bias voltage Vbias. This embodiment does not limit the specific implementation of the bias voltage generation circuit 350. For example, the bias voltage generation circuit 350 includes a current source Ibias5 and a transistor MN52. A first terminal (such as a drain) of the transistor MN52 is coupled to the current source Ibias5. A second terminal (such as a source) of the transistor MN52 is coupled to a reference voltage source VSS. A control terminal (such as a gate) of the transistor MN52 is coupled to the first terminal of the transistor MN52 and to the control terminals of each transistor MN51_1 to MN51_n to provide the bias voltage Vbias.

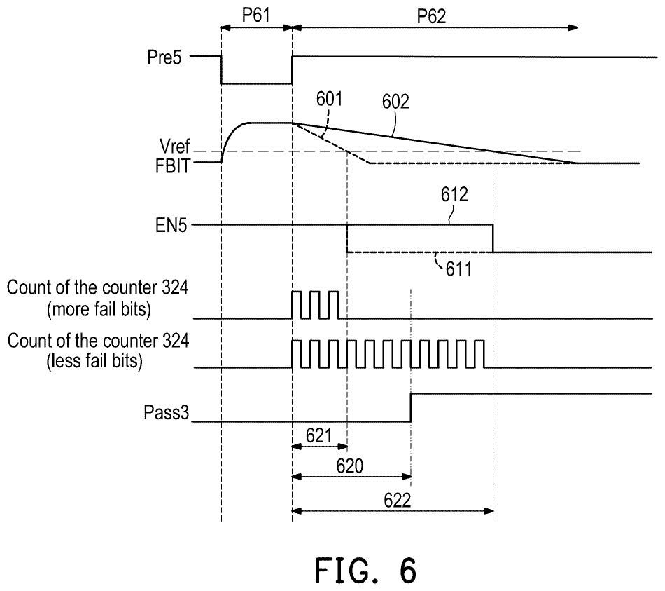

FIG. 6 is a signal diagram illustrating a precharge period P61 and a determination period P62 according to an embodiment of the disclosure. Please refer to FIG. 5 and FIG. 6. Based on the control of the precharge control signal Pre5, the precharging transistor MP51 is turned on during the precharge period P61 to precharge the capacitive conductor 330. Therefore, the node voltage FBIT of the capacitive conductor 330 is pulled up to a precharge level (such as the voltage level of the power voltage source VDD or another voltage level). The precharging transistor MP51 is turned off during the determination period P62 after the precharge period P61 to stop precharging the capacitive conductor 330. The greater the number of fail bits in the present logic values of different data buses DBUS_1 to DBUS_n, the greater the discharge current Ifail, causing a faster falling speed of the node voltage FBIT (as shown by dashed line 601 in FIG. 6). Conversely, the fewer the fail bits in the present logic values of different data buses DBUS_1 to DBUS_n, the smaller the discharge current Ifail, causing a slower falling speed of the node voltage FBIT (as shown by solid line 602 in FIG. 6).

In the embodiment shown in FIG. 5, the judgment circuit 320 includes a reference voltage generation circuit 321, a comparator 322, a clock generation circuit 323, a counter 324, and a comparator 325. The reference voltage generation circuit 321 generates an original reference voltage Vref. The comparator 322 is coupled to the reference voltage generation circuit 321 to receive the original reference voltage Vref. The comparator 322 is also coupled to the capacitive conductor 330 to receive the node voltage FBIT. The comparator 322 compares the node voltage FBIT with the original reference voltage Vref during the determination period P62. The comparator 322 generates an enable signal EN5 based on a comparison result between the node voltage FBIT and the original reference voltage Vref. The greater the number of fail bits in the present logic values of different data buses DBUS_1 to DBUS_n, the faster the falling speed of the node voltage FBIT, causing the enable signal EN5 to transition to a disabled state earlier (as shown by dashed line 611 in FIG. 6). Conversely, the fewer the fail bits in the present logic values of different data buses DBUS_1 to DBUS_n, the slower the falling speed of the node voltage FBIT, causing the enable signal EN5 to transition to a disabled state later (as shown by solid line 612 in FIG. 6).

The clock generation circuit 323 generates an original clock signal CK5. An enable terminal of the counter 324 is coupled to an output terminal of the comparator 322 to receive the enable signal EN5. The enable signal EN5 controls a counting time length of the counter 324, which serves as the falling time length. Based on the control of the enable signal EN5, the counter 324 counts the original clock signal CK5 during the counting time length to generate a count value CNT5. The greater the number of fail bits in the present logic values of different data buses DBUS_1 to DBUS_n, the earlier the enable signal EN5 transitions to a disabled state, causing the counting time length of the counter 324 to be shorter (as shown by a falling time length 621 in FIG. 6). Conversely, the fewer the fail bits in the present logic values of different data buses DBUS_1 to DBUS_n, the later the enable signal EN5 transitions to a disabled state, causing the counting time length of the counter 324 to be longer (as shown by a falling time length 622 in FIG. 6).

The comparator 325 is coupled to an output terminal of the counter 324 to receive the count value CNT5. The comparator 325 compares the count value CNT5 with a reference value REF5 during the determination period P62 (which is equivalent to the judgment circuit 320 comparing the falling time length with a reference time length 620). The comparator 325 determines whether the present logic values of different data buses DBUS_1 to DBUS_n are failed based on a comparison result between the count value CNT5 and the reference value REF5. The greater the number of fail bits in the present logic values of different data buses DBUS_1 to DBUS_n, the shorter the falling time length (such as the falling time length 621). Because the falling time length 621 is shorter than the reference time length 620 (that is, the count value CNT5 is smaller than the reference value REF5), the result signal PASS3 is at a low logic level (indicating that the present logic values fail the check). Conversely, the fewer the fail bits in the present logic values of different data buses DBUS_1 to DBUS_n, the longer the counting time length of the counter 324 (such as the falling time length 622). Once the count value CNT5 is greater than the reference value REF5 (that is, the falling time length 622 is longer than the reference time length 620), the result signal PASS3 is immediately pulled high (indicating that the present logic values pass the check).

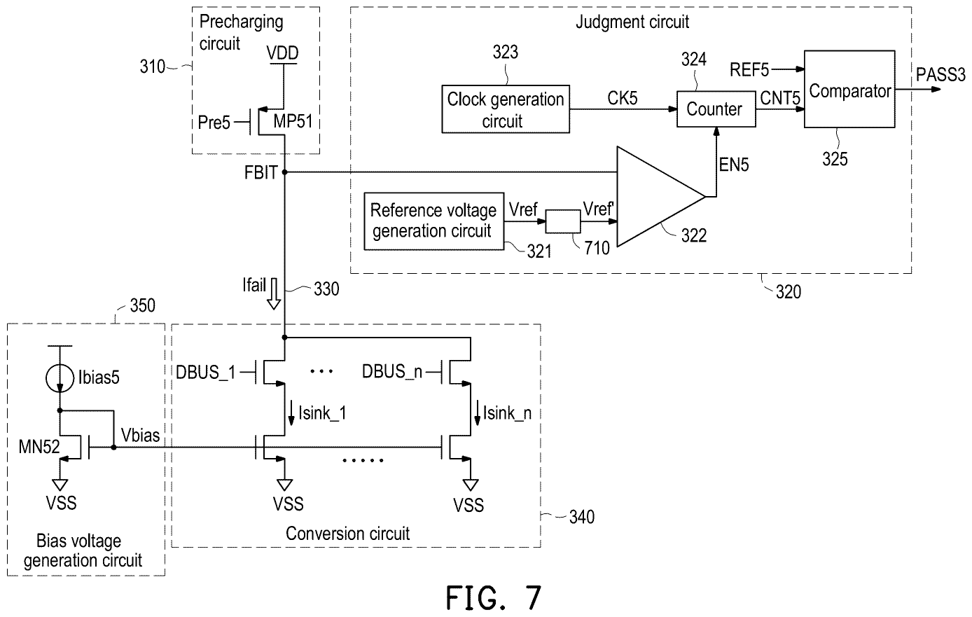

FIG. 7 is a schematic diagram of a circuit block illustrating the judgment circuit 320 and the conversion circuit 340 according to another embodiment. The judgment circuit 320 and the conversion circuit 340 shown in FIG. 7 may be one of many implementation examples of the judgment circuit 320 and the conversion circuit 340 shown in FIG. 3. The precharging circuit 310, the judgment circuit 320, the capacitive conductor 330, the conversion circuit 340, and the bias voltage generation circuit 350 shown in FIG. 7 may be referenced with the related description of FIG. 5 and will not be redundantly described.

In the embodiment shown in FIG. 7, the judgment circuit 320 includes the reference voltage generation circuit 321, a temperature compensation circuit 710, the comparator 322, the clock generation circuit 323, the counter 324, and the comparator 325. The reference voltage generation circuit 321, the comparator 322, the clock generation circuit 323, the counter 324, and the comparator 325 shown in FIG. 7 may be referenced with the related description of FIG. 5 and FIG. 6 and will not be redundantly described. The judgment circuit 320 shown in FIG. 7 further includes the temperature compensation circuit 710. An input terminal of the temperature compensation circuit 710 is coupled to an output terminal of the reference voltage generation circuit 321 to receive the original reference voltage Vref. The temperature compensation circuit 710 compensates the original reference voltage Vref based on a present temperature to generate a compensated reference voltage Vref′, which serves as the reference voltage for the comparator 322.

In response to an increase in the present temperature, a current of the current source Ibias5 slightly decreases, causing the discharge time of the capacitive conductor 330 to become longer. The judgment circuit 320 shown in FIG. 7 uses the temperature compensation circuit 710 to appropriately adjust the original reference voltage Vref to generate the compensated reference voltage Vref′ that varies with temperature. When the temperature rises, the compensated reference voltage Vref′ correspondingly increases, thereby allowing the counter 324 to stop counting earlier.

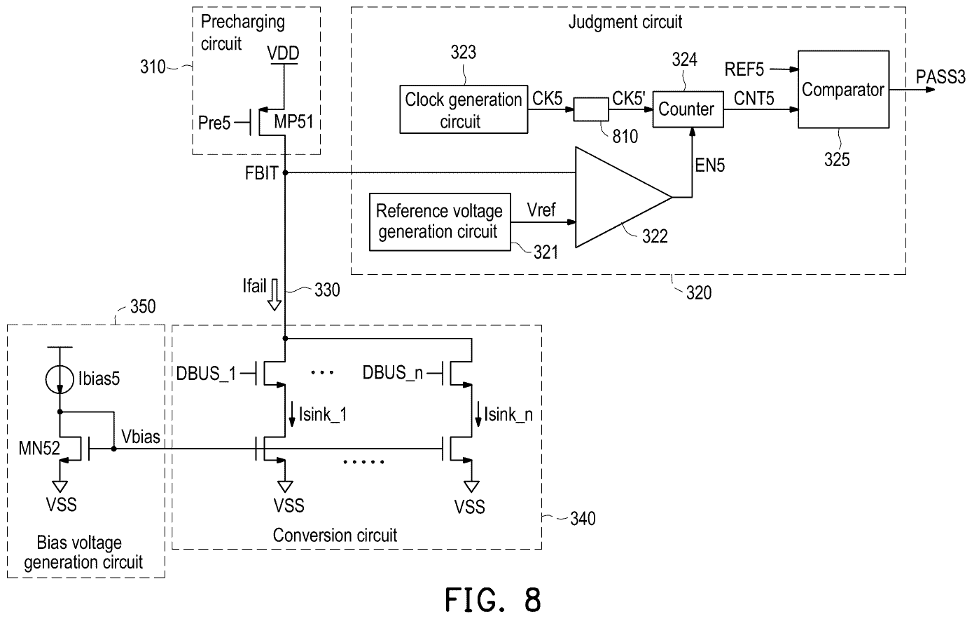

FIG. 8 is a schematic diagram of a circuit block illustrating the judgment circuit 320 and the conversion circuit 340 according to yet another embodiment. The judgment circuit 320 and the conversion circuit 340 shown in FIG. 8 may be one of many implementation examples of the judgment circuit 320 and the conversion circuit 340 shown in FIG. 3. The precharging circuit 310, the judgment circuit 320, the capacitive conductor 330, the conversion circuit 340, and the bias voltage generation circuit 350 shown in FIG. 8 may be referenced with the related description of FIG. 5 and will not be redundantly described.

In the embodiment shown in FIG. 8, the judgment circuit 320 includes the reference voltage generation circuit 321, the comparator 322, the clock generation circuit 323, a temperature compensation circuit 810, the counter 324, and the comparator 325. The reference voltage generation circuit 321, the comparator 322, the clock generation circuit 323, the counter 324, and the comparator 325 shown in FIG. 8 may be referenced with the related description of FIG. 5 and FIG. 6 and will not be redundantly described. The judgment circuit 320 shown in FIG. 8 further includes the temperature compensation circuit 810. An input terminal of the temperature compensation circuit 810 is coupled to an output terminal of the clock generation circuit 323 to receive the original clock signal CK5. The temperature compensation circuit 810 compensates the original clock signal CK5 based on a present temperature to generate a compensated clock signal CK5′, which serves as the clock signal for the counter 324.

In response to an increase in the present temperature, a current of the current source Ibias5 slightly decreases, causing the discharge time of the capacitive conductor 330 to become longer. The judgment circuit 320 shown in FIG. 8 uses the temperature compensation circuit 810 to appropriately adjust the original clock signal CK5 to generate the compensated clock signal CK5′ that varies with temperature. When the temperature rises, the compensated clock signal CK5′ correspondingly slows down, thereby extending the falling time length.

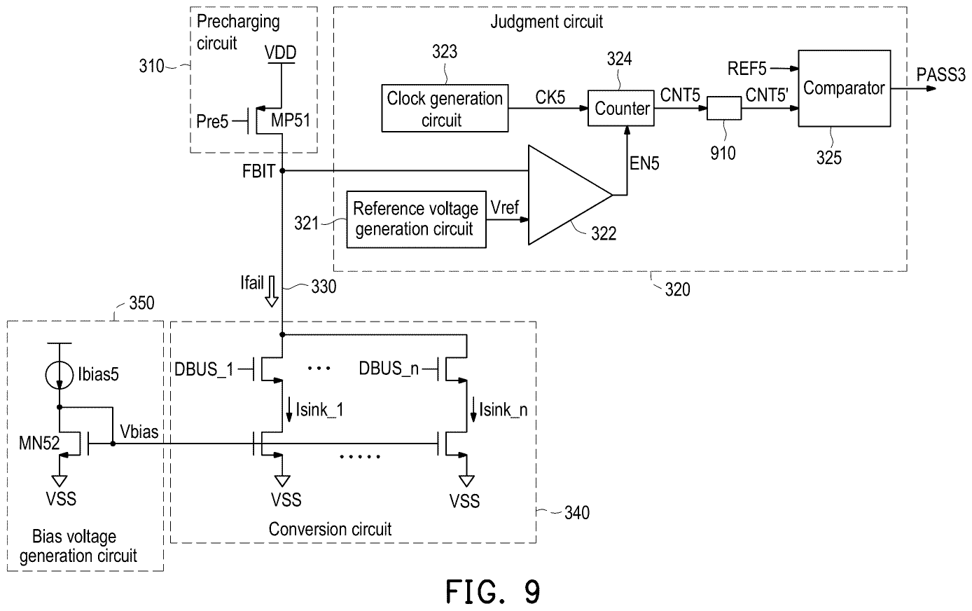

FIG. 9 is a schematic diagram of a circuit block illustrating the judgment circuit 320 and the conversion circuit 340 according to yet another embodiment. The judgment circuit 320 and the conversion circuit 340 shown in FIG. 9 may be one of many implementation examples of the judgment circuit 320 and the conversion circuit 340 shown in FIG. 3. The precharging circuit 310, the judgment circuit 320, the capacitive conductor 330, the conversion circuit 340, and the bias voltage generation circuit 350 shown in FIG. 9 may be referenced with the related description of FIG. 5 and will not be redundantly described.

In the embodiment shown in FIG. 9, the judgment circuit 320 includes the reference voltage generation circuit 321, the comparator 322, the clock generation circuit 323, the counter 324, a temperature compensation circuit 910, and the comparator 325. The reference voltage generation circuit 321, the comparator 322, the clock generation circuit 323, the counter 324, and the comparator 325 shown in FIG. 9 may be referenced with the related description of FIG. 5 and FIG. 6 and will not be redundantly described. The judgment circuit 320 shown in FIG. 9 further includes the temperature compensation circuit 910. An input terminal of the temperature compensation circuit 910 is coupled to an output terminal of the counter 324 to receive the count value CNT5. The temperature compensation circuit 910 compensates the count value CNT5 based on a present temperature to generate a compensated count value CNT5′.

The comparator 325 is coupled to an output terminal of the temperature compensation circuit 910 to receive the compensated count value CNT5′. The comparator 325 compares the compensated count value CNT5′ with a reference value REF5 during the determination period. The comparator 325 determines whether the present logic values of different data buses DBUS_1 to DBUS_n are failed based on a comparison result between the compensated count value CNT5′ and the reference value REF5. In response to an increase in the present temperature, a current of the current source Ibias5 slightly decreases, causing the discharge time of the capacitive conductor 330 to become longer. The judgment circuit 320 shown in FIG. 9 uses the temperature compensation circuit 910 to appropriately adjust the count value CNT5 to generate the compensated count value CNT5′ that varies with temperature. When the temperature rises, the compensated count value CNT5′ correspondingly decreases, thereby compensating for the increase in the discharge time of the capacitive conductor 330.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A fail bits detection device for a flash memory, the fail bits detection device comprising:
a capacitive conductor;
a precharging circuit coupled to the capacitive conductor, wherein the precharging circuit precharges the capacitive conductor during a precharge period;
a conversion circuit, wherein a plurality of input terminals of the conversion circuit are coupled to a plurality of different data buses of a page buffer of the flash memory, the conversion circuit converts a plurality of present logic values of the plurality of different data buses into a discharge current during a determination period after the precharge period, a current terminal of the conversion circuit is coupled to the capacitive conductor, and the conversion circuit draws the discharge current from the capacitive conductor during the determination period; and
a judgment circuit coupled to the capacitive conductor, wherein the judgment circuit checks a node voltage of the capacitive conductor during the determination period, the judgment circuit determines a falling time length based on a falling speed of the node voltage during the determination period, and the judgment circuit determines whether the plurality of present logic values of the plurality of different data buses are failed based on the falling time length.

2. The fail bits detection device according to claim 1, wherein the capacitive conductor comprises a metal-routing capacitor for storing a precharge charge outputted by the precharging circuit during the precharge period.

3. The fail bits detection device according to claim 1, wherein
a present logic value of a target data bus of the plurality of different data buses is a first logic value, indicating that a programming result of a corresponding word line in the flash memory is a failure;
the present logic value of the target data bus is a second logic value, indicating that the programming result of the corresponding word line in the flash memory is a pass;
in response to the present logic value of the target data bus indicating that the programming result is the failure, the conversion circuit converts the present logic value of the target data bus into a corresponding current component of the discharge current; and
in response to the present logic value of the target data bus indicating that the programming result is the pass, the conversion circuit abandons converting the present logic value of the target data bus into the corresponding current component of the discharge current.

4. The fail bits detection device according to claim 1, wherein
the precharging circuit stops precharging the capacitive conductor during the determination period after the precharge period;
the conversion circuit draws the discharge current from the capacitive conductor during the determination period, such that the node voltage continuously falls during the determination period, wherein the more data buses of the plurality of different data buses indicate that a programming result is a failure, the greater the discharge current, causing the falling speed of the node voltage to be faster;
the judgment circuit compares the node voltage with a reference voltage during the determination period;
the judgment circuit determines the falling time length based on a comparison result between the node voltage and the reference voltage;
the judgment circuit compares the falling time length with a reference time length; and
the judgment circuit determines whether the present logic values of the plurality of different data buses are failed based on a comparison result between the falling time length and the reference time length.

5. The fail bits detection device according to claim 1, wherein the precharging circuit comprises:
a precharging transistor, wherein a first terminal of the precharging transistor is coupled to a power voltage source, a second terminal of the precharging transistor is coupled to the capacitive conductor, and a control terminal of the precharging transistor is controlled by a precharge control signal.

6. The fail bits detection device according to claim 1, wherein the conversion circuit comprises:
a plurality of switches, wherein a first terminal of each of the plurality of switches is coupled to the capacitive conductor, and a control terminal of each of the plurality of switches is coupled to a corresponding one of the plurality of different data buses of the page buffer; and
a plurality of first transistors, wherein a first terminal of each of the plurality of first transistors is coupled to a second terminal of a corresponding one of the plurality of switches, a second terminal of the each of the plurality of first transistors is coupled to a first reference voltage source, and a control terminal of the each of the plurality of first transistors is controlled by a bias voltage.

7. The fail bits detection device according to claim 6 further comprising:
a bias voltage generation circuit coupled to the conversion circuit to provide the bias voltage.

8. The fail bits detection device according to claim 7, wherein the bias voltage generation circuit comprises:
a current source; and
a second transistor, wherein a first terminal of the second transistor is coupled to the current source, a second terminal of the second transistor is coupled to a second reference voltage source, and a control terminal of the second transistor is coupled to the first terminal of the second transistor and the control terminal of the each of the plurality of first transistors to provide the bias voltage.

9. The fail bits detection device according to claim 1, wherein the judgment circuit comprises:
a first comparator coupled to the capacitive conductor to receive the node voltage, wherein the first comparator compares the node voltage with a reference voltage during the determination period;
a counter having an enable terminal coupled to an output terminal of the first comparator, wherein the first comparator controls a counting time length of the counter as the falling time length based on a comparison result between the node voltage and the reference voltage, and the counter counts a clock signal during the counting time length to generate a count value; and
a second comparator coupled to an output terminal of the counter to receive the count value, wherein the second comparator compares the count value with a reference value during the determination period, the second comparator determining whether the present logic values of the plurality of different data buses are failed based on a comparison result between the count value and the reference value.

10. The fail bits detection device according to claim 9, wherein the judgment circuit further comprises:
a reference voltage generation circuit generating an original reference voltage; and
a temperature compensation circuit having an input terminal coupled to an output terminal of the reference voltage generation circuit to receive the original reference voltage, wherein the temperature compensation circuit compensates the original reference voltage based on a present temperature to generate a compensated reference voltage as the reference voltage for the first comparator.

11. The fail bits detection device according to claim 9, wherein the judgment circuit further comprises:
a clock generation circuit generating an original clock signal; and
a temperature compensation circuit having an input terminal coupled to an output terminal of the clock generation circuit to receive the original clock signal, wherein the temperature compensation circuit compensates the original clock signal based on a present temperature to generate a compensated clock signal as the clock signal for the counter.

12. The fail bits detection device according to claim 1, wherein the judgment circuit comprises:
a first comparator coupled to the capacitive conductor to receive the node voltage, wherein the first comparator compares the node voltage with a reference voltage during the determination period;
a counter having an enable terminal coupled to an output terminal of the first comparator, wherein the first comparator controls a counting time length of the counter as the falling time length based on a comparison result between the node voltage and the reference voltage, and the counter counts a clock signal during the counting time length to generate a count value;
a temperature compensation circuit having an input terminal coupled to an output terminal of the counter to receive the count value, wherein the temperature compensation circuit compensates the count value based on a present temperature to generate a compensated count value; and
a second comparator coupled to an output terminal of the temperature compensation circuit to receive the compensated count value, wherein the second comparator compares the compensated count value with a reference value during the determination period, and the second comparator determines whether the present logic values of the plurality of different data buses are failed based on a comparison result between the compensated count value and the reference value.

13. A fail bits detection method for a flash memory, the fail bits detection method comprising:
precharging, by a precharging circuit of the flash memory, a capacitive conductor of the flash memory during a precharge period, wherein the precharging circuit is coupled to the capacitive conductor;
converting, by a conversion circuit of the flash memory, a plurality of present logic values of a plurality of different data buses of a page buffer of the flash memory into a discharge current during a determination period after the precharge period, wherein a plurality of input terminals of the conversion circuit are coupled to the plurality of different data buses;
drawing, by the conversion circuit, the discharge current from the capacitive conductor during the determination period, wherein a current terminal of the conversion circuit is coupled to the capacitive conductor;
checking, by a judgment circuit of the flash memory, a node voltage of the capacitive conductor during the determination period, wherein the judgment circuit is coupled to the capacitive conductor;
determining, by the judgment circuit, a falling time length based on a falling speed of the node voltage during the determination period; and
determining, by the judgment circuit, whether the present logic values of the plurality of different data buses are failed based on the falling time length.

14. The fail bits detection method according to claim 13, wherein the capacitive conductor comprises a metal-routing capacitor for storing a precharge charge outputted by the precharging circuit during the precharge period.

15. The fail bits detection method according to claim 13, wherein a present logic value of a target data bus of the plurality of different data buses being a first logic value indicates that a programming result of a corresponding word line in the flash memory is a failure, the present logic value of the target data bus being a second logic value indicates that the programming result of the corresponding word line in the flash memory is a pass, and the fail bits detection method further comprises:
in response to the present logic value of the target data bus indicating that the programming result is the failure, converting, by the conversion circuit, the present logic value of the target data bus into a corresponding current component of the discharge current; and
in response to the present logic value of the target data bus indicating that the programming result is the pass, abandoning, by the conversion circuit, converting the present logic value of the target data bus into the corresponding current component of the discharge current.

16. The fail bits detection method according to claim 13, further comprising:
stopping, by the precharging circuit, precharging the capacitive conductor during the determination period after the precharge period;
drawing, by the conversion circuit, the discharge current from the capacitive conductor during the determination period, such that the node voltage continuously falls during the determination period, wherein the more data buses of the plurality of different data buses indicate that a programming result is a failure, the greater the discharge current, causing the falling speed of the node voltage to be faster;
comparing, by the judgment circuit, the node voltage with a reference voltage during the determination period;
determining, by the judgment circuit, the falling time length based on a comparison result between the node voltage and the reference voltage;
comparing, by the judgment circuit, the falling time length with a reference time length; and
determining, by the judgment circuit, whether the present logic values of the plurality of different data buses are failed based on a comparison result between the falling time length and the reference time length.
